(19) United States
(12) Patent Application Publication
(10) Pub. No.: US 2008/0286932 A1
(43) Pub. Date: Nov. 20, 2008

(54) Method of manufacturing semiconductor device

(75) Inventor: Jong Won Sun, Gokseong-gun (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 12/152,800

(22) Filed: May 15, 2008

(30) Foreign Application Priority Data
May 17, 2007 (KR) 10-2007-0047982

(51) Int. Cl. H01L 21/336

(52) U.S. Cl. 438/303; 257/E21.409

(57) ABSTRACT

A method of manufacturing a semiconductor device may include the steps of: forming a doped polysilicon film by implanting or incorporating dopant ions simultaneously with forming a silicon film; forming a doped polysilicon pattern by patterning the doped polysilicon film; forming a spacer on sides of the doped polysilicon pattern; and forming source and drain regions using the polysilicon pattern and the spacer as a mask.

The present application claims priority under 35 U.S.C. 119 and 35 U.S.C. 365 to Korean Patent Application No. 10-2007-0047981 (filed on May 17, 2007), which is hereby incorporated by reference in its entirety.

### BACKGROUND

Embodiments of the invention relate to a method of manufacturing a semiconductor device.

In the background semiconductor devices, a gate electrode may be formed using polysilicon in order to reduce gate capacity and improve the switching characteristics of a circuit. The gate electrode is generally formed by implanting ions into the polysilicon layer. Ions are implanted into the polysilicon layer and a cleaning process cleaning impurities and ions, etc. generated when implanting ions is then performed. And, after forming the polysilicon layer implanted with impurities, a cleaning process cleaning impurities generated in a heat treatment process may be performed. In other words, forming the polysilicon layer implanted with the impurity may include the ion implantation process and the heat treatment process.

### SUMMARY

Embodiments of the invention provide a simplified process when forming a gate electrode capable of shortening manufacturing time.

There is provided a method of manufacturing a semiconductor device comprising the steps of: forming a doped polysilicon film by implanting or otherwise depositing dopant ions simultaneously with a silicon film; forming a doped polysilicon pattern by patterning the doped polysilicon film; forming a spacer on sides of the doped polysilicon pattern; and forming source and drain regions using the polysilicon pattern and the spacer as a mask.

### BRIEF DESCRIPTION OF THE DRAWINGS

FIGS. 1 to 4 are cross-sectional views showing an exemplary method of manufacturing a semiconductor device.

### DETAILED DESCRIPTION OF THE EMBODIMENTS

The embodiments will be described in detail with reference to the accompanying drawings.

Hereinafter, embodiments of the invention will be described in detail with reference to the accompanying drawings.

In a description of the embodiments, the “on” and/or “over” includes all components formed directly on an underlying structure or formed over the underlying layers, on which one or more other layers may exist, in the case where a layer is formed “on” or “over” the underlying structure or layer.

The thickness or size in the drawings may be exaggerated, omitted, or simplified to better illustrate and explain the present invention. Also, the size of each component is not necessarily to scale.

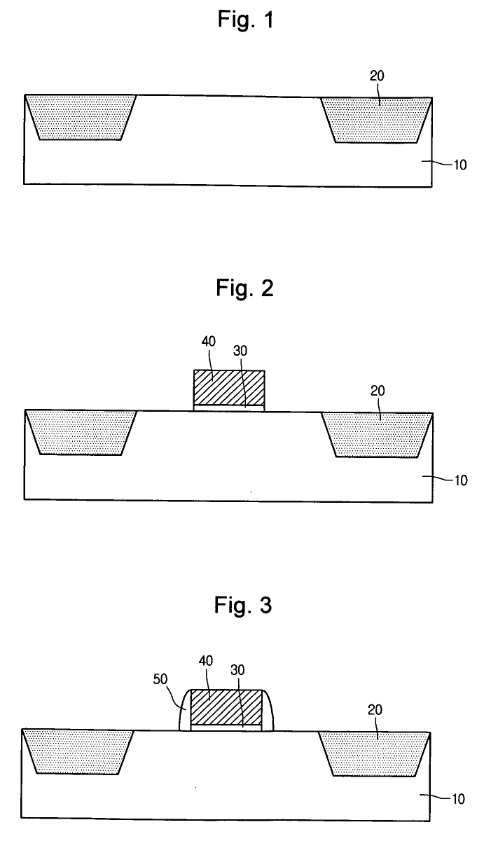

A method of manufacturing a semiconductor device according to the embodiment will be described with reference to FIGS. 1 to 4.

As shown in FIG. 1, a trench is formed by patterning and selectively etching a semiconductor substrate 10. A thin liner oxide may be grown along the sidewalls and bottom of the trench, and a thin silicon nitride layer may be deposited thereon. Then, a borophosphosilicate glass (BPSG) or silicon oxide (SiO₂) film is deposited in the trench (e.g., to fill a gap remaining in the trench), and a chemical mechanical polishing process is performed thereon, thereby forming a device isolation layer 20. The device isolation layer 20 is a region for insulating or electrically isolating various devices later formed on the semiconductor substrate 10.

After the device isolation layer 20 is formed, an oxide film is grown (e.g., by conventional wet or dry thermal oxidation) on the semiconductor substrate 10 and a doped polysilicon layer is deposited on the thermal oxide film as described herein. The thermal oxide film and the doped polysilicon layer are patterned to form a gate oxide pattern 30 and a polysilicon pattern 40, as shown in FIG. 2. The oxide film forms a gate oxide in a gate region of the device.

The doped polysilicon layer may be formed using a furnace or a rapid thermal processing apparatus, and in one embodiment, a relatively conventional method for forming a polysilicon layer having a thickness of 1350 to 1650 Å is used (e.g., chemical vapor deposition of silane [SiH₄], a halosilane [e.g., SiH₂Cl₂], disilane [Si₂H₆], trisilane [Si₃H₈], etc.) and modified to further include the dopant. Thus, at the same time, the polysilicon layer may be implanted with ions or otherwise formed to contain dopant ions, for example at a temperature of 565 to 585° C. and an atmosphere containing one or more sources of phosphorus ions providing a phosphorous concentration of 1.5×10²⁰˜2.5×10²⁰ atoms/cm³. Sources of phosphorus ions include phosphine, a phosphorous trihalide (e.g., PCl₃, PBr₃, etc.), and mono-, di- or trialkyl- and/or -arylphosphines (e.g., methylphosphine, dimethylphosphine, trimethylphosphine, dimethylchlorophos-phine, ethylphosphine, diethylphosphine, triethylphosphine, ethyldichlorophosphine, butylphosphine [which may be n-, i- or t-butylphosphine], dibutylphosphine, tributylphosphine, phenylphosphine, triphenyl-phosphine, etc.). Alternatively, the polysilicon layer may be formed to contain other dopant ions, such as arsenic, at a similar temperature (e.g., from 500 to 700° C.) and an atmosphere containing one or more sources of arsenic ions in a similar concentration (e.g., from 1×10¹⁹˜5×10²¹ atoms/cm³). Suitable gas or vapor concentrations in the furnace providing a target dopant concentration in the polysilicon layer may be readily determined from known or empirically derived deposition rates of such dopants under the conditions of chemical vapor deposition employed.

While temperatures such as those described in the preceding paragraph may form amorphous or polycrystalline silicon (“polysilicon”), to the extent an amorphous or insufficiently polycrystalline silicon is formed, further annealing at the same or slightly higher temperature (e.g., from 600 to 800° C.), for a length of time sufficient to effectively crystallize substantially all of the amorphous silicon can be easily determined and/or derived by one skilled in the art. And, the polysilicon layer containing (or “implanted” with) the dopant ions is covered with a photosensitive film, which is then patterned by photolithography. After development, the exposed doped polysilicon layer and the thermal oxide film are then etched to form an oxide film pattern 30 and a polysilicon pattern 40. The polysilicon pattern 40 may be a gate electrode.

When forming the polysilicon, the ions are deposited to form doped polysilicon, so that the cleaning process and the heat treatment process added in the conventional ion implantation can be omitted. Therefore, the process steps and the manufacturing time can be shortened, making it possible to improve the productivity of the semiconductor device.

As shown in FIG. 3, a spacer 50 is formed at both sides of the polysilicon pattern 40. The spacer 50 may comprise one or more oxide and/or nitride films, and is generally formed by conformal deposition of one or more relatively thin dielectric layers on the semiconductor substrate 10, including the oxide film 30 and the polysilicon pattern 40, and anisotropically etching the dielectric layer(s). In one embodiment, the dielectric layers comprise sequentially deposited first oxide, nitride and second oxide layers to form an ONO (oxide-nitride-oxide) spacer 50. Thus, the spacer 50 may have a structure formed from the ONO film(s), but is not limited thereto. For example, the spacer 50 may have an oxide-nitride structure.

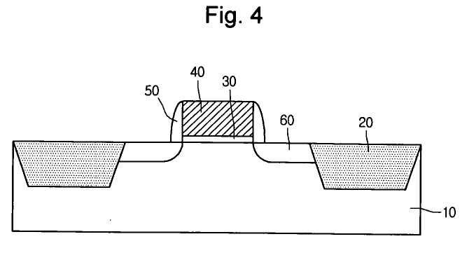

As shown in FIG. 4, one or more ion implantation processes are performed using the spacer 50 and the polysilicon pattern 40 as a mask to form source/drain region 60 on the semiconductor substrate 10. However, a lightly doped source-drain extension region (not shown) may be formed by implantation of a relatively smaller dose of dopant ions into the substrate 10 at a relatively lower energy than that used to form the source/drain regions 60, but prior to forming the spacer 50 (e.g., using only the gate 40 as a mask).

Thereafter, although not shown, an interlayer insulating film is formed on the semiconductor substrate 10 and is selectively etched to form via holes exposing each source/drain region 60 and the gate 40. Then, a contact plug is formed in each via hole. The polysilicon pattern 40 and the source/drain regions 60 may be electrically connected to each other by overlying metallization after the formation of the contact plug.

The values of the polysilicon gate and the conventional polysilicon gate Rs (sheet resistance) formed as described above are measured as follows.

TABLE 1

| Zone | Gate | Rs (Ω/sq.) |
|---|---|---|
| Upper | undoped poly+ion implant | 87.6 |
| | doped poly | 86.5 |
| Center | undoped poly+ion implant | 89.3 |
| | doped poly | 83.0 |
| Lower | undoped poly+ion implant | 93.1 |
| | doped poly | 89.5 |

The ‘undoped poly+ion implant’ is a conventional polysilicon gate formed by conventional ion implantation, heat treatment, and a cleaning process after the polysilicon is formed. The “doped poly” refers to an exemplary polysilicon gate formed by simultaneously depositing the dopant ions along with silicon, for forming doped polysilicon.

As can be appreciated from the value of Rs, the Rs value of the conventional gate and the gate of the embodiment is little different, and arguably superior for the doped poly of the present invention, making it possible to change a conventionally ion-implanted gate to the doped poly gate of the present invention. Therefore, the gate of the present device has similar or the same conducting property as the conventional gate, but can be formed with fewer process steps as compared with the conventional gate. Thereby, the occurrence of impurities or defects may be reduced.

As described above, the present method performs the ion implantation or incorporates dopant ions simultaneously with the formation of the silicon for forming polysilicon, making it possible to omit the cleaning and heat treatment processes in the conventional ion implantation. Therefore, turnaround time is remarkably reduced as compared to the conventional gate electrode forming scheme, making it possible to improve the productivity of the semiconductor device.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a semiconductor device comprising the steps of:
forming a doped polysilicon film by depositing dopant ions simultaneously with a silicon film;
forming a doped polysilicon pattern by patterning the doped polysilicon film;
forming a spacer on sides of the doped polysilicon pattern; and
forming source and drain regions using the polysilicon pattern and the spacer as a mask.

2. The method according to claim 1, wherein the doped polysilicon film is formed in a furnace or an RTP apparatus.

3. The method according to claim 1, wherein the doped polysilicon film is performed in an atmosphere providing a dopant concentration of 1.5×10²⁰ to 2.5×10²⁰ atoms/cm³.

4. The method according to claim 1, wherein the dopant ion comprises phosphorus ions or arsenic ions.

5. The method according to claim 1, wherein the doped polysilicon film is formed at a temperature of 565 to 585° C.

6. The method according to claim 1, wherein the doped polysilicon film has a thickness of 1350 to 1650 Å.

7. The method according to claim 1, further comprising forming an oxide film on the semiconductor substrate before forming the doped polysilicon film.

8. The method according to claim 7, wherein forming the oxide film comprises growing a thermal oxide on the semiconductor substrate.

9. The method according to claim 1, wherein the spacer comprises an ONO (oxide-nitride-oxide) film.

10. The method according to claim 1, wherein the spacer comprises an ON (oxide-nitride) film.
